(19) United States
(12) Patent Application Publication
(10) Pub. No.: US 2009/0067550 A1
(43) Pub. Date: Mar. 12, 2009

(54) METHOD AND SYSTEM FOR REDUNDANCY-BASED DECODING OF AUDIO CONTENT

(76) Inventors: Arie Heiman, Rannana (IL); Arkady Molev-Shteiman, Cliffwood, NJ (US)

Correspondence Address: MCANDREWS HELD & MALLOY, LTD, 500 WEST MADISON STREET, SUITE 3400, CHICAGO, IL, 60661, US

(21) Appl. No.: 11/971,626

(22) Filed: Jan. 9, 2008

Related U.S. Application Data
(60) Provisional application No. 60/970,354, filed on Sep. 6, 2007.

(51) Int. Cl. H03D 1/00; H04L 27/06

(52) U.S. Cl. 375/340; 700/94

(57) ABSTRACT

Aspects of a method and system for redundancy-based decoding of audio content are provided. A redundancy parameter may be generated for verifying a decoded bit sequence that comprises audio content, such as a decoded audio frame. The redundancy parameter may be a cyclic redundancy check (CRC) value and/or a length of frame value associated with the decoded audio frame. Information associated with the redundancy parameter may be comprised within a header of the audio frame. For example, a length of frame value, a bitrate value, a sampling rate frequency value, and/or a frame padding value may be comprised within the header of the audio frame. If the verification of the decoded audio frame fails, subsequent decoding of the previously decoded audio frame may be performed by imposing at least one physical constraint that results from the encoding of the audio frame.

### CROSS-REFERENCE TO RELATED APPLICATIONS/INCORPORATION BY REFERENCE

This application makes reference to, claims priority to, and claims the benefit of U.S. Provisional Application Ser. No. 60/970,354 filed Sep. 6, 2007.

This patent application makes reference to:
U.S. patent application Ser. No. 11/189,509 filed on Jul. 26, 2005;
U.S. patent application Ser. No. 11/189,634 filed on Jul. 26, 2005; and
U.S. Provisional Patent Application Ser. No. 60/957,096 filed on Aug. 21, 2007.

Each of the above stated applications is hereby incorporated by reference in its entirety.

### FIELD OF THE INVENTION

Certain embodiments of the invention relate to handling of music files. More specifically, certain embodiments of the invention relate to a method and system for redundancy-based decoding of audio content.

### BACKGROUND OF THE INVENTION

In some conventional receivers and/or electronic media players, improvements may require extensive system modifications that may be very costly and, in some cases, may even be impractical. Determining the right approach to achieve design improvements may depend on the optimization of a system to a particular modulation type and/or to the various kinds of noises that may be introduced by a transmission channel. For example, the optimization of a receiver system or media player may be based on whether the signals being received, generally in the form of successive symbols or information bits, are interdependent. Signals received from and/or generated by, for example, a convolutional encoder, may be interdependent signals, that is, signals with memory. In this regard, a convolutional encoder may generate NRZI or continuous-phase modulation (CPM), which is generally based on a finite state machine operation.

One method or algorithm for signal detection in a receiver system or media player that decodes convolutional encoded data is maximum-likelihood sequence detection or estimation (MLSE). The MLSE is an algorithm that performs soft decisions while searching for a sequence that minimizes a distance metric in a trellis that characterizes the memory or interdependence of the transmitted signal. In this regard, an operation based on the Viterbi algorithm may be utilized to reduce the number of sequences in the trellis search when new signals are received. Another method or algorithm for signal detection of convolutional encoded data that makes symbol-by-symbol decisions is maximum a posteriori probability (MAP). The optimization of the MAP algorithm is based on minimizing the probability of a symbol error. In many instances, the MAP algorithm may be difficult to implement because of its computational complexity.

In audio applications, for example, improvements in the design and implementation of receivers or media players for decoding convolutional encoded audio data may require modifications to the application of the MLSE algorithm, the Viterbi algorithm, and/or the MAP algorithm in accordance with the manner in which the signal was transmitted. In this regard, the overall performance of the receiver or media player may therefore depend on the ability of the system to optimize the decoding of audio content.

Audio content, such as music, sounds, and/or voice data, may generally be comprised within an audio file format that is used to digitally store the audio data on a computer system, for example. There may be many different types of formats that may be utilized for storing audio files. Some files may be generated without using data compression while others may be based on lossless or lossy compression techniques. For example, the Apple Lossless and the lossless Windows Media Audio (WMA) formats are based on lossless compression techniques while MPEG-1 Audio Layer 3 (MP3) and lossy WMA are based on lossy compression techniques. The overall performance of a receiver or media player may therefore depend on the ability of the system to optimize the decoding of content within an audio file format.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for redundancy-based decoding of audio content, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating a multilayer system for improving audio content decoding, in accordance with an embodiment of the invention.

FIG. 2 is a block diagram illustrating a multilayer system with a processor and memory for improving audio content decoding, in accordance with an embodiment of the invention.

FIG. 3 is a diagram illustrating an exemplary frame for an audio file format, which may be utilized in accordance with an embodiment of the invention.

FIG. 4A is a flow diagram illustrating exemplary steps in the application of redundancy to a multilayer process for audio content decoding, in accordance with an embodiment of the invention.

FIG. 4B is a flow diagram illustrating exemplary steps in the application of a constraint algorithm to a received frame for audio content decoding, in accordance with an embodiment of the invention.

FIG. 5A is diagram illustrating an exemplary search process for a T hypothesis that meets CRC constraint for decoding audio content, in accordance with an embodiment of the invention.

FIG. 5B is a diagram illustrating exemplary buffer content during the search process described in FIG. 5A, in accordance with an embodiment of the invention.

FIG. 5C is a diagram illustrating exemplary buffer content when CRC and trace back pointers are calculated simultaneously during the search process described in FIG. 5A, in accordance with an embodiment of the invention.

FIG. 6 is a graph illustrating exemplary set of sequences that meets CRC and audio physical constraints, in accordance with an embodiment of the invention.

FIG. 7 is a block diagram illustrating an iterative multilayer approach for improving audio content decoding when burst processing is utilized, in accordance with an embodiment of the invention.

FIG. 8 is a flow diagram illustrating exemplary steps in the iterative multilayer approach for improving audio content decoding, in accordance with an embodiment of the invention.

### DETAILED DESCRIPTION OF THE INVENTION

Certain embodiments of the invention may be found in a method and system for redundancy-based decoding of audio content. A redundancy parameter may be generated for verifying a decoded bit sequence that comprises audio content, such as a decoded audio frame. The redundancy parameter may be a cyclic redundancy check (CRC) value and/or a length of frame value associated with the decoded audio frame. Information associated with the redundancy parameter may be comprised within a header of the audio frame. For example, a length of frame value, a bitrate value, a sampling rate frequency value, and/or a frame padding value may be comprised within the header of the audio frame. If the verification of the decoded audio frame fails, subsequent decoding of the previously decoded audio frame may be performed by imposing at least one physical constraint that results from the encoding of the audio frame.

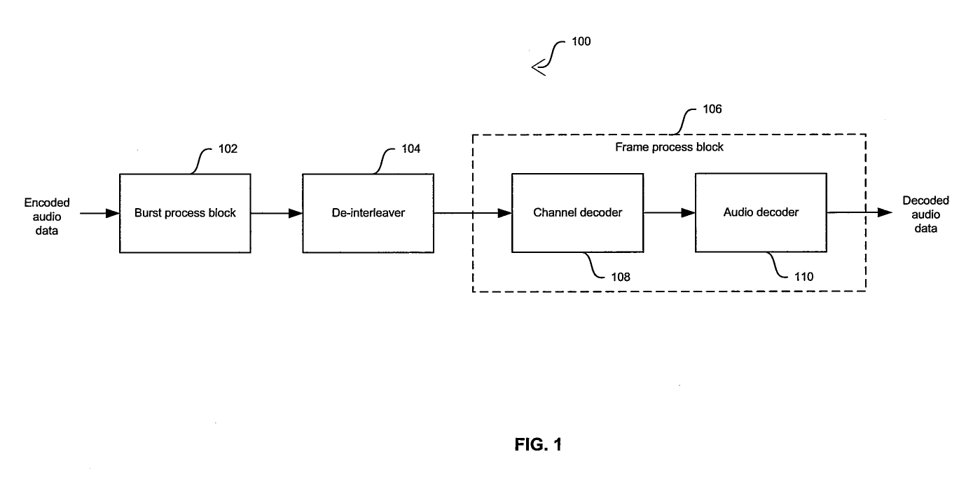

FIG. 1 is a block diagram illustrating a multilayer system for improving audio content decoding, in accordance with an embodiment of the invention. Referring to FIG.1, there is shown a media player or receiver 100 that comprises a burst process block 102, a de-interleaver 104, and a frame process block 106. The frame process block 106 may comprise a channel decoder 108 and an audio decoder 110. The receiver 100 may comprise suitable logic, circuitry, and/or code that may enable reception of and processing of signals, such as signals comprising audio content, for example. The receiver 100 may support signal received via wired or wireless transmission. The receiver 100 may enable decoding of interdependent signals, such as signals that comprise convolutional encoded data, for example, by utilizing redundancy inherent in the signal that may result from the coding operation. The receiver 100 may also enable a multilayer approach for improving the decoding of interdependent signals or signals with memory. In this regard, the receiver 100 may enable a burst process and/or a frame process when processing the received interdependent signals. The multilayer approach performed by the receiver 100 may be compatible with a plurality of modulation standards utilized for signal transmission, for example.

The burst process block 102 may comprise suitable logic, circuitry, and/or code that may enable a burst process portion of the decoding operation of the receiver 100. The burst process block 102 may comprise, for example, a channel estimation operation and a channel equalization operation. Results from the channel estimation operation may be utilized by the channel equalization operation to generate a plurality of data bursts based on a maximum-likelihood sequence estimation (MLSE) operation, for example. In audio applications, the data bursts generated by the burst process block 102 may correspond to audio data bursts, for example. The output of the burst process block 102 may be transferred to the de-interleaver 104. The de-interleaver 104 may comprise suitable logic, circuitry, and/or code that may enable multiplexing of bits from a plurality of data bursts received from the burst process block 102 to form the frame inputs to the frame process block 106. Interleaving may be utilized to reduce the effect of channel fading distortion, for example. In audio applications, the frame inputs to the frame process block 106 may correspond to audio frame inputs, for example.

The channel decoder 108 may comprise suitable logic, circuitry, and/or code that may enable decoding of the bit sequences in the input frames received from the de-interleaver 104. The channel decoder 108 may enable utilizing a Viterbi algorithm during a Viterbi operation to improve the decoding of the input frames. The audio decoder 110 may comprise suitable logic, circuitry, and/or code that may enable audio specific processing operations on the results of the channel decoder 108 for specified audio file formats such as MP3, and/or lossy/lossless WMA, for example. The audio decoder 110 may be utilized to recognize and/or decode more than one audio file format, for example. The audio decoder 110 may be utilized to reconstruct an encoded audio file or an encoded audio sequence for playback via a speaker, a headset, and/or ear buds, for example. Notwithstanding, the audio decoder 110 need not be so limited.

In some instances, audio decoding applications need not require burst process operations. In this regard, operations provided by the burst process block 102 and/or the de-interleaver 104 may be disabled and/or by-passed, for example, to allow direct frame process operations by the frame process block 106 on the received audio frames.

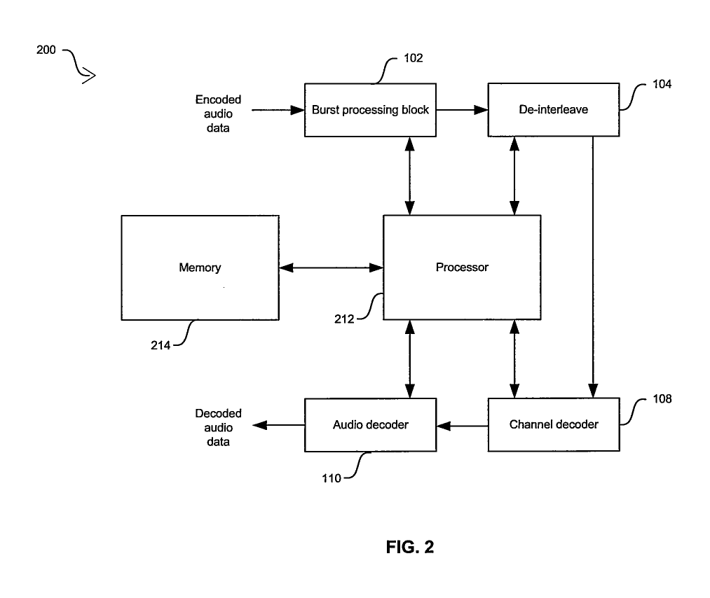

FIG. 2 is a block diagram illustrating a multilayer system with a processor and memory for improving audio content decoding, in accordance with an embodiment of the invention. Referring to FIG. 2, there is shown a media player or receiver system 200 that may comprise a processor 212 and a memory 214. The receiver system 200 may also comprise the burst process block 102, a de-interleaver 104, the channel decoder 108 and the audio decoder 110 disclosed in FIG. 1. The processor 212 may comprise suitable logic, circuitry, and/or code that may enable performing of computations and/or management operations. The processor 212 may also enable communication with and/or control of at least a portion of the burst process block 102, the de-interleaver 104, the channel decoder 108 and the audio decoder 110. The memory 214 may comprise suitable logic, circuitry, and/or code that may enable storing of data and/or control information. The memory 214 may enable storing of information that may be utilized and/or that may be generated by the burst process block 102, the de-interleaver 104, the channel decoder 108 and the audio decoder 110. In this regard, information may be transferred to and from the memory 214 via the processor 212, for example. The processor 212 and the memory 214 may be utilized by the receiver system 200 to enable redundancy-based decoding operations that utilize physical constraints for optimizing the decoding of convolutional encoded data that comprises audio content, for example.

Regarding the frame process operation in the receiver 100 in FIG. 1 or in the receiver system 200 in FIG. 2, one approach for decoding convolutional encoded data is to utilize a maximum a posteriori probability (MAP) algorithm. This approach may utilize a priori statistics of the source bits such that a one-dimensional a priori probability, p(bᵢ), may be generated, where bᵢ corresponds to a current bit in the bit sequence to be encoded. To determine the MAP sequence, the Viterbi transition matrix calculation may need to be modified. This approach may be difficult to implement in instances where complicated physical constraints and when the correlation between bits bᵢ and bⱼ, where i and j are far apart, may not be easily determined. In cases where a parameter domain has a high correlation, the MAP algorithm may be difficult to implement. Moreover, the MAP algorithm may not be utilized in cases where inherent redundancy, such as for CRC, is part of the physical constraints.

Regarding the frame process operation in the receiver 100 in FIG. 1 or in the receiver system 200 in FIG. 2, another approach for decoding convolutional encoded data is to find the maximum-likelihood sequence estimate (MLSE) for a bit sequence. This may involve searching for a sequence X in which the conditional probability P(X/R) is a maximum, where X is the transmitted sequence and R is the received sequence, by using, for example, the Viterbi algorithm. In some instances, the received signal R may comprise an inherent redundancy as a result of the encoding process by the signals source. This inherent redundancy may be utilized in the decoding process by developing a MLSE algorithm that may be adapted to meet at least some of the physical constrains of the signals source. The use of physical constraints in the MLSE may be expressed as finding a maximum of the conditional probability P(X/R), where the sequence X meets a set of physical constrains C(X) and the set of physical constrains C(x) may depend on the source type and on the application. In this regard, for audio, music, and/or multimedia applications the source type may be an audio source.

For certain data formats, for example, the inherent redundancy of the physical constraints may result from the packaging of the data and the generation of a redundancy verification parameter, such as a cyclic redundancy check (CRC), for the packaged data. Moreover, decoding data generated by entropy encoders or variable length coding (VLC) operations may also meet some internal constraints. For example, VLC operations utilize a statistical coding technique where short codewords may be utilized to represent values that occur frequently and long codewords may be utilized to represent values that occur less frequently.

The maximum-likelihood sequence estimate (MLSE) for a bit sequence may be a preferred approach for decoding convolutional encoded data. A general solution for the maximum of the conditional probability P(X/R), where R meets a certain set of physical constraints C(X), for the MLSE may still be difficult to implement. In this regard, an efficient solution may require a suboptimal solution that takes into consideration the complexity and the implementation requirements of utilizing physical constraints in the decoding operation. In audio applications, determining the appropriate physical constraints for the audio content may be necessary in order to implement an efficient solution for redundancy-based decoding operations.

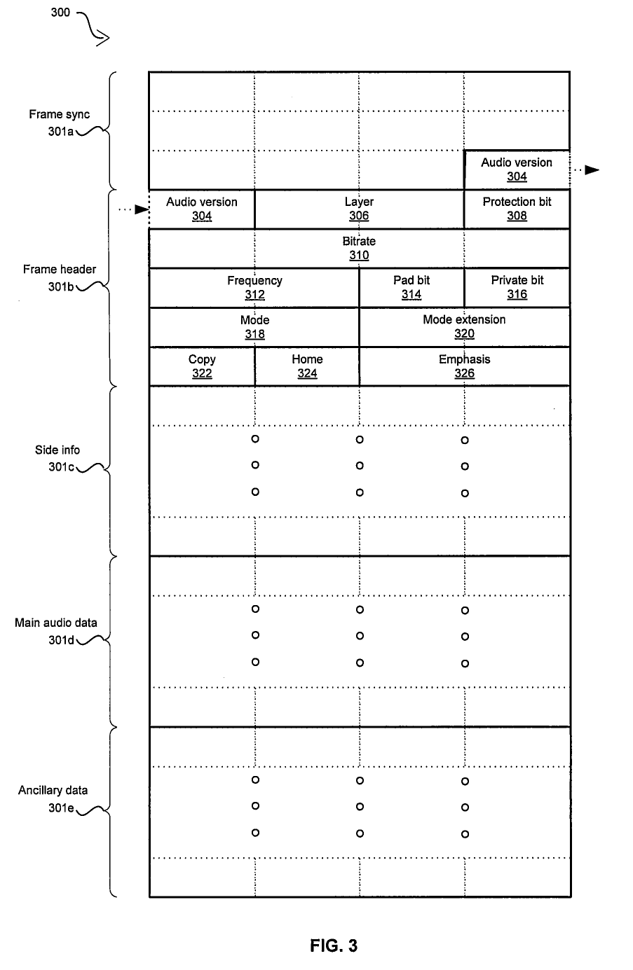

FIG. 3 is a diagram illustrating an exemplary frame for an audio file format, which may be utilized in accordance with an embodiment of the invention. Referring to FIG. 3, there is shown an exemplary audio file frame 300 that may correspond to an audio file frame for the MP3 audio file format, for example. In this regard, a single MP3 audio file may comprise a plurality of audio file frames such as the audio file frame 300. The audio file frame 300 may comprise a plurality of fields or sections. A first field may be the frame synchronization (sync) 301a, a second field may be the frame header 301b, a third field may be a side information (info) 301c, a fourth field may be a main data 301d, and a last field may be an ancillary data 301e. Notwithstanding, the audio file frame 300 need not be so limited and the contents of the audio file frame 300 may be organized in a different manner. Moreover, audio file formats other than MP3 may utilize a different field organization than that shown in FIG. 3.

The frame sync 301a may comprise a plurality of bits that may be utilized to synchronize the contents of the audio file frame 300. For example, a decoder may look or search through at least a portion of a file comprising the audio file frame 300 to detect or finding the frame sync 301a in order to decode the audio file frame 300. The frame sync 301a may comprise 11 or 12 set bits (0xFFF), for example. For audio file formats other than MP3, the frame sync 301a may have a corresponding frame field that may comprise fewer or more set bits than the number utilized in the frame sync 301a, for example.

The frame header 301b may comprise a plurality of fields. For example, the frame header 301b may comprise an audio version 304, a layer 306, a protection bit 308, a bitrate 310, a frequency 312, a pad bit 314, a private bit 316, a mode 318, a mode extension 320, a copy 322, a home 324, and an emphasis 326. The audio version 304 may comprise at least one bit that may be utilized to indicate the MPEG audio version ID utilized in the compression of the audio content in the audio file frame 300. For example, when two bits are utilized, ‘00’ may correspond to MPEG version 2.5, ‘10’ may correspond to MPEG version 2 (ISO/IEC 13818-3), ‘11’ may correspond to MPEG version 1 (ISO/IEC 11172-3), and ‘01’ may be reserved. The MPEG version 2.5 may be an extension of the standard that may be utilized in low bit rate files. When the MPEG version 2.5 is not supported by, for example, a decoder utilized to decode the received audio file frame, then utilizing a 12-bit frame sync 301a may provide better synchronization.

The layer 306 may comprise at least one bit that may be utilized to indicate the layer description. For example, when two bits are utilized, ‘01’ may correspond to Layer III, ‘10’ may correspond to Layer II, ‘11’ may correspond to Layer I, and ‘00’ may be reserved. The protection bit 308 may comprise at least one bit that may indicate whether the audio file frame 300 is protected by, for example, CRC. In this regard, when a single bit is utilized, a ‘0’ may indicate that the audio file frame 300 is protected by CRC while a ‘1’ may indicate that the audio file frame 300 is not protected by CRC. The CRC may be a 16-bit CRC that may follow the frame header 301b. In some instances, the CRC may be adjacent to and/or comprised within the side info 301c and/or within the main audio data 301d, for example. The CRC may be utilized to enable redundancy-based decoding of audio file frames, for example.

The bitrate 310 may comprise a plurality of bits that may be utilized to indicate the bitrate index in kilobits-per-second (kbps) utilized in encoding the audio content comprised within audio file frame 300. The following table illustrates exemplary bitrates that may be supported in MP3 when four bits are utilized to indicate the bitrates:

TABLE 1
Bitrate index.

| bits | V1, L1 | V1, L2 | V1, L3 | V2, L1 | V2, L2 & L3 |
|---|---|---|---|---|---|
| 0000 | free | free | free | free | free |
| 0001 | 32 | 32 | 32 | 32 | 8 |
| 0010 | 64 | 48 | 40 | 48 | 16 |
| 0011 | 96 | 56 | 48 | 56 | 24 |
| 0100 | 128 | 64 | 56 | 64 | 32 |
| 0101 | 160 | 80 | 64 | 80 | 40 |
| 0110 | 192 | 96 | 80 | 96 | 48 |
| 0111 | 224 | 112 | 96 | 112 | 56 |
| 1000 | 256 | 128 | 112 | 128 | 64 |
| 1001 | 288 | 160 | 128 | 144 | 80 |
| 1010 | 320 | 192 | 160 | 160 | 96 |
| 1011 | 352 | 224 | 192 | 176 | 112 |
| 1100 | 384 | 256 | 224 | 192 | 128 |
| 1101 | 416 | 320 | 256 | 224 | 144 |
| 1110 | 448 | 384 | 320 | 256 | 160 |
| 1111 | bad | bad | bad | bad | bad |

where V1 corresponds to MPEG version 1, V2 corresponds to MPEG version 2 and 2.5, L1 corresponds to Layer I, L2 corresponds to Layer II, L3 corresponds to Layer III, ‘free’ may indicate a free format, and ‘bad’ may indicate that the ‘1111’ value may not be a valid value and/or that it may not allowed. Since MPEG files may have variable bit rate (VBR), it may be possible for audio file frames 300 in an MP3 file to be created utilizing a different bitrate.

The frequency 312 may comprise at least one bit that may be utilized to indicate the sampling rate frequency utilized in creating the audio file frame 300. The following table illustrates exemplary sampling rate frequencies that may be supported in MP3 when two bits are utilized to indicate the sampling rate frequencies:

TABLE 2
Sampling rate frequency index.

| bits | MPEG1 | MPEG2 | MPEG2.5 |
|---|---|---|---|
| 00 | 44100 | 22050 | 11025 |
| 01 | 48000 | 24000 | 12000 |
| 10 | 32000 | 16000 | 8000 |
| 11 | reserved | reserved | reserved |

where all frequency values are in Hz.

The pad bit 314 may comprise at least one bit that may be utilized to indicate padding of the audio file frame 300. For example, when one bit is utilized, a ‘0’ may indicate that the frame is not padded while a ‘1’ may indicate that the frame is padded. In this regard, padding may be utilized to fit the bitrates exactly. For example, for a 128 kbps bitrate at 44.1 KHz sampling rate frequency, Layer II applications may utilize 418 byte and 417 byte long frames to get as close as possible to the 128 kbps bitrate. For Layer I, the slot may be 32 bits long while for Layer II and Layer III the slot may be 8 bits long, for example.

The private bit 316 may comprise at least one bit that may be utilized for specific needs of an application. In this regard, the private bit 316 may be utilized to carry information that may be utilized in redundancy-based decoding applications, for example. The mode 318 may comprise at least one bit that may be utilized to indicate the type of channel mode. For example, when two bits are utilized, a ‘00’ may indicate a stereo mode, a ‘01’ may indicate a joint stereo mode, a ‘10’ may indicate a dual channel or two mono channels, and a ‘11’ may indicate a single channel or mono. The mode extension 320 may comprise at least one bit that may be utilized in joint stereo mode to co-join channel data, for example. In this regard, the mode extension may utilize two bits to indicate the appropriate extension operation.

The copy 322 may comprise at least one bit that may be utilized to indicate whether the contents in the audio file frame 300 are copyrighted. For example, when a single bit is utilized, ‘0’ may indicate that the copyright is off, that is, the contents are not copyrighted, and a ‘1’ may indicate that the copyright is on, that is, the content are copyrighted. The home 324 may comprise at least one bit that may be utilized to indicate whether the contents are original or a copy of an original. For example, when a single bit is utilize, a ‘0’ may indicate that the contents are a copy of an original file while a ‘1’ may indicate that the contents are those of an original file. The emphasis 326 may comprise at least one bit that may be utilized to indicate the emphasis bit in an original recording. In some instances, the emphasis 326 may utilize two bits to for emphasis indication.

The side info 301c may comprise at least one bit that may be utilized to provide additional information that may be based on the audio version 304 and/or the mode 318. In this regard, the side info 301c may be a variable bit length structure, for example. The main audio data 301d may comprise a plurality of bits that may correspond to the compressed or encoded sound content within the audio file frame 300. The ancillary data 301e may comprise a plurality of bits that may be utilized to provide user defined data such as song or audio file title, for example.

When the protection bit 308 indicates that a CRC for the audio file frame 300 is available, the CRC may be utilized for redundancy-based decoding of the audio file frame 300 and the audio contents within the audio file frame 300. Moreover, additional information within the frame header 301b may be utilized to indicate redundancy or physical characteristics of the contents of the audio file frame 300 and which may be utilized for redundancy-based decoding applications. For example, the bitrate 310, the frequency 312, and/or the pad bit 314 may be utilized to indicate the length of the audio file frame 300. The length of the audio file frame 300 may be based on the appropriate encoding of the audio contents and may therefore be based on the physical information, such as musical and/or voice spectral content, for example, contained within the audio information in the main audio data 301d. Notwithstanding, other audio file frame formats may utilize a field in, for example, a frame header, to provide direct information as to the frame length which may be utilized for redundancy-based decoding applications.

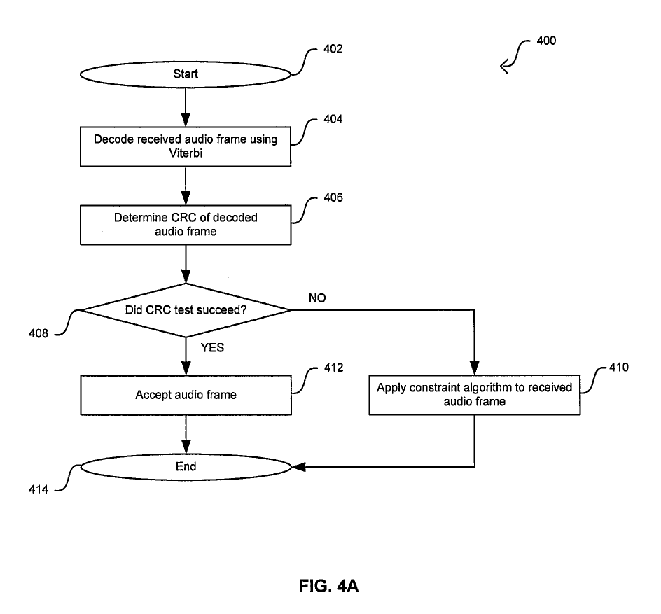

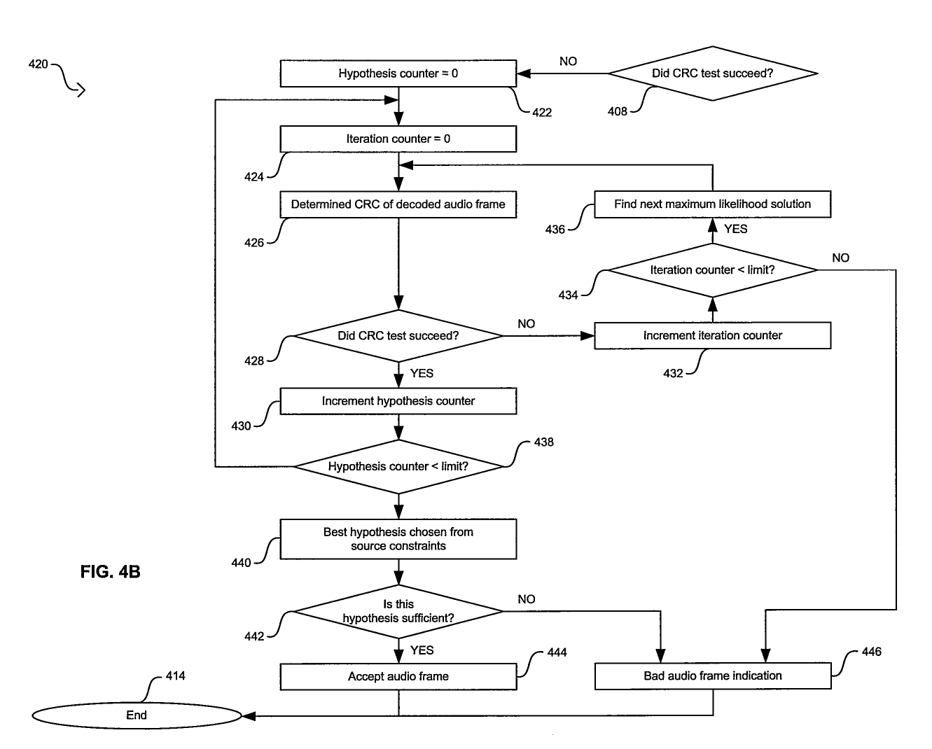

FIG. 4A is a flow diagram illustrating exemplary steps in the application of redundancy to a multilayer process for audio content decoding, in accordance with an embodiment of the invention. Referring to FIG. 4A, after start step 402, in step 404, an audio receiver or media player, such as the receiver 100 in FIG. 1 or the receiver system 200 in FIG. 2, for example, may decode a received audio frame in the frame process block 106 by utilizing the Viterbi algorithm. A received audio frame may correspond to a bit sequence comprising audio content, for example. In step 406, a redundancy verification parameter, such as the CRC, may be determined for the decoded audio frame. In step 408, the audio receiver may determine whether the CRC verification test was successful. When the CRC verifies the decoded audio frame, the operation may proceed to step 412 where the decoded audio frame is accepted for further processing, such as application specific audio decoding, for example. After step 412, the operation may proceed to end step 414.

Returning to step 408, when the CRC verification test is not successful for the decoded audio frame, the process may proceed to step 410. In step 410, the audio receiver may perform a redundancy algorithm that may be utilized to provide a decoding performance that may result in equal or reduced decoding errors when reconstructing the audio content than those that may occur from utilizing the standard Viterbi algorithm. After step 410, the operation may proceed to end step 414.

For some audio applications, for example, the redundancy algorithm may comprise searching for the MLSE that may also meet the CRC condition and the physical constraints. In this regard, a set of k bit sequences {S1, S2, . . . , Sk} may be determined from the MLSE that meet the CRC constraint. Once the set of k sequences is determined, a best sequence, Sb, may be determined that also meets at least one of a plurality of physical constraints associated with a specified audio content.

FIG. 4B is a flow diagram illustrating exemplary steps in the application of a constraint algorithm to a received frame for audio content decoding, in accordance with an embodiment of the invention. Referring to FIG. 4B, when the CRC verification test is not successful for the decoded audio frame in step 408 in FIG. 4A, the operation may proceed to step 422. In step 422, a hypothesis counter may be set to an initial counter value to indicate a first hypothesis for consideration, for example. The initial counter value in step 422 may be zero, for example. After step 422, an iteration counter may be set to an initial counter value in step 424 to indicate a first maximum likelihood solution, for example. The initial counter value in step 424 may be zero, for example. In step 426, the CRC of the decoded audio frame may be determined.

In step 428, the audio receiver may determine whether the CRC verification test was successful for the current hypothesis. When the CRC verification test is not successful, the operation may proceed to step 432. In step 432, the iteration counter may be incremented. After step 432, in step 434, the audio receiver may determine whether the iteration counter is less than a predetermined limit. When the iteration counter is higher or equal to the predetermined limit, the operation may proceed to step 446 where a bad audio frame indication is generated. When the iteration counter is less than the predetermined limit, the operation may proceed to step 436 where a next maximum likelihood solution may be determined. After step 436, the operation may proceed to step 426 where the CRC of the decoded audio frame may be determined based on the maximum likelihood solution determined in step 426.

Returning to step 428, when the CRC verification test is successful, the operation may proceed to step 430. In step 430, the hypothesis counter may be incremented. After step 430, in step 438, the audio receiver may determine whether the hypothesis counter is less than a predetermined limit. When the hypothesis counter is less than the predetermined limit, the operation may proceed to step 424 where the iteration counter may be set to an initial value. When the hypothesis counter is equal to the predetermined limit, the operation may proceed to step 440 where the best hypothesis may be chosen from the source constraints.

After step 440, in step 442, the audio receiver may determine whether the best hypothesis chosen in step 440 is sufficient to accept the decoded audio frame. When the chosen hypothesis is sufficient to accept the decoded audio frame, the operation may proceed to step 444 where the decoded audio frame may be accepted. When the chosen hypothesis is not sufficient to accept the decoded frame, the operation may proceed to step 446 where a bad audio frame indication is generated. After step 444 or step 446, the operation may proceed to end step 414 in FIG. 4A.

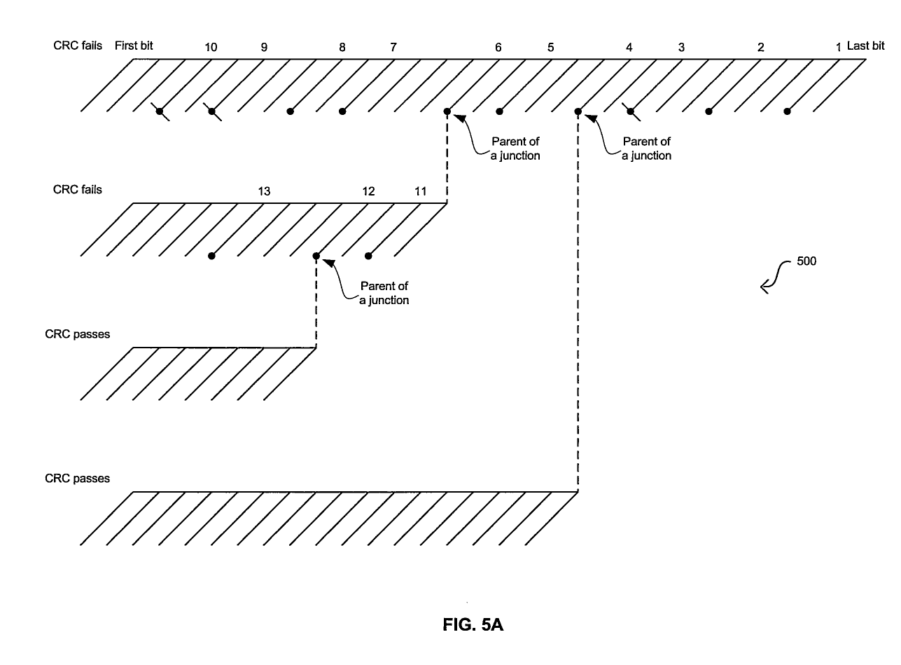

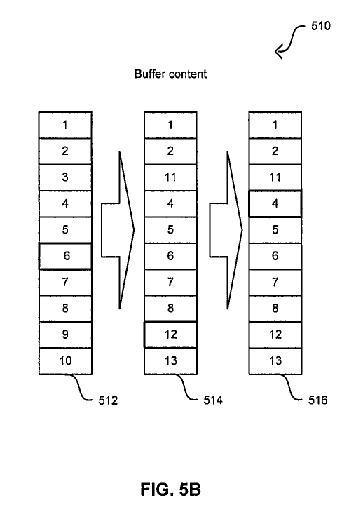

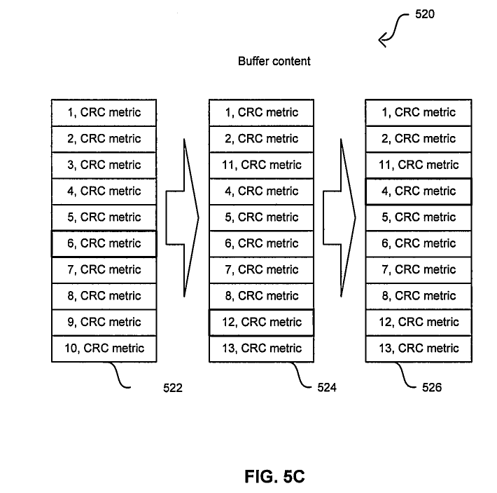

FIG. 5A is diagram illustrating an exemplary search process for a T hypothesis that meets CRC constraint for decoding audio content, in accordance with an embodiment of the invention. Referring to FIG. 5A, there is shown a search tree 500 that may correspond to an exemplary sequence search process that may start with the reduced set of estimated bit sequences generated by a Viterbi operation. The estimated bit sequence may be generated from at least a portion of a received audio frame or bit sequence comprising audio content. In this regard, the top horizontal row corresponds to a set of N trellis junctions that may result from the Viterbi operation. The main sequence metric and the metric of main sequence junctions may be obtained during the Viterbi calculation. The metric of other sequences may be obtained from the sum of the parent sequence metric and the junction metric. Each of the trellis junctions is shown as a diagonal line and corresponds to an estimated bit sequence from the Viterbi operation. The estimated bit sequences in the top row do not meet the CRC constraint. In the redundancy algorithm, a set of estimated bit sequences may be selected from those in the top row. As shown, 10 estimated bit sequences may be selected, for example, from the N trellis junctions. The 10 selected estimated bit sequences may be shown as having a dark circle at the end of the diagonal line. In this regard, the selection may depend on a metric parameter, where the metric parameter may, in some instances, comprise a channel metric portion and a physical constraint metric portion.

The search process for a T hypothesis that meets the CRC or redundancy verification parameter for audio decoding applications may start with the selected trellis junction with the highest metric. In this example, the junction labeled 6 has the highest metric and the search process may start at that point. A new search tree 500 branch or row may be created from the junction labeled 6 and a trace back pointer may be utilized to track the search operation. The new branch or row results in three additional estimated bit sequences or three junctions labeled 11 through 13. As a result, the three junctions in the top row with the lowest metrics, junctions 3, 9, and 10, may be dropped. This is shown by a small dash across the dark circle at the end of the diagonal line. Again, the new branch or row is verified for CRC. As shown, the CRC fails for this new branch and a next branch may be created from the junction with the highest metric or junction 12 as shown. In this instance, the branch that results from junction 12 meets the CRC constraint and the search process may return to the top row and to the junction with the next highest metric. The estimated bit sequence associated with junction 12 may be selected as one of the bit sequences for the set of k sequences {S1, S2, . . . , Sk}.

Junction 4 represents the next highest metric after junction 6 on the top row and a new branch or row may be created from junction 4. In this instance, the new branch meets the CRC constraint and the estimated bit sequence associated with junction 4 may be selected as one of the bit sequences for the set of k sequences {S1, S2, . . . , Sk}. This approach may be followed until the limit of k sequences is exceeded or the search from all the remaining selected junctions is performed. In this regard, a plurality of trace back pointers may be calculated during the search operation. The size of the set of k bit sequences {S1, S2, . . . , Sk} may vary.

FIG. 5B is a diagram illustrating exemplary buffer content during the search process described in FIG. 5A, in accordance with an embodiment of the invention. Referring to FIG. 5B, there is shown a buffer content 510 that may correspond to the junction labels under consideration during the search process. For example, state 512 may correspond to the initial 10 junctions in the search operation. In this regard, junction 6 is highlighted to indicate that it corresponds to the highest metric value and is the starting point of a new branch or row. The state 514 may correspond to the next set of 10 junctions. In this instance, junctions 3, 9, and 10 have been replaced with junctions 11, 12, and 13 that resulted from the branch created from junction 6. Junction 12 is highlighted to indicate that is corresponds to the highest metric value and is the starting point of a new branch or row. The state 516 may correspond to the next set of 10 junctions. In this instance, junction 4 is highlighted to indicate that is corresponds to the highest metric value and is the starting point of a new branch or row. Trace back pointers may be calculated at each state to track the search process.

FIG. 5C is a diagram illustrating exemplary buffer content when CRC and trace back pointers are calculated simultaneously during the search process described in FIG. 5A, in accordance with an embodiment of the invention. Referring to FIG. 5C, there is shown a buffer content 520 that may correspond to the junction labels under consideration during the search process and the corresponding CRC calculations, for example. As with FIG. 5B, the buffer content 520 may vary its contents based on a current state. For state 522, state 524, and state 526, the contents that correspond to the current junctions under consideration are the same as in state 512, state 514, and state 516 in FIG. 5B respectively. However, in order to simplify the search process for T hypothesis, the CRC and the trace back pointers for the states may be calculated simultaneously. This approach is possible because the CRC may be calculated as sum(bᵢRᵢ), where Rᵢ is the remainder of xi/g(x), where g(x) is the generator polynomial of the CRC, and bᵢ is the value of the bit i. The CRC metric of each sequence may be kept or stored in the buffer content 520. The CRC metric may be obtained as the sum of the biRi values from the junction to the last bit, and may also be determined as the sum of the parent sequence CRC metric and sum of the biRi values from junction to its parent. The sequence may meet the CRC condition if the CRC metric is equal to the sum of the biRi values from first bit to the junction. The values for Rᵢ may be stored in, for example, a look up table.

Once the set of k sequences {S1, S2, . . . , Sk} has been determined by following the search as described in FIGS. 5A-5C, the redundancy algorithm may require that the audio receiver or media player, such as the receiver 100 in FIG. 1 or the receiver system 200 in FIG. 2, for example, selects one of the bit sequences as the best bit sequence, Sb, that meets the CRC constrain and the physical constrains with the highest level of confidentiality. The best bit sequence may also be referred to as the decoded output bit sequence of the multilayer process.

For each of the candidate bit sequences in the set of k bit sequences {S1, S2, . . . , Sk}, a set of TI different physical constraint tests, {Test(j), . . . , Test(T1)}, may be performed. The physical constraint tests correspond to tests of quantifiable characteristics of the type of audio data received for a particular audio application, for example. The scores of the physical constraint tests for an i^{th} bit sequence, {T_SC(i, j), . . . , T_SC(i, T1)}, may be utilized to determine whether the bit sequence passed or failed a particular test. One example of quantifiable characteristics of audio content in MP3 frames may be information regarding the variable length of the audio frame, the bitrate, the sampling rate frequency, and/or the bit padding. For example, when T_SC(i, j)>0, the i^{th} bit sequence is said to have failed the j^{th} physical constraint test. When the T_SC(i, j)<=0, the i^{th} bit sequence is said to have passed the j^{th} physical constraint test. In some instances, when the value of a test score is smaller, the reliability of the score may be increased.

Once the physical constraint tests are applied to the candidate estimated bit sequences, the following exemplary approach may be followed: when a score is positive, the candidate bit sequence may be rejected; for a particular physical constraint test, the candidate with the best score or with the lowest score value may be found; the candidate that is selected as the best score for the most number of tests may be selected as the best bit sequence, Sb.

Table 3 illustrates an exemplary embodiment of the invention in which a set of five candidate bit sequences, {S1, S2, S3, S4, and S5}, may be tested using a set of four physical constraint tests, {Test(1), Test(2), Test(3), and Test(4)}. The scores may be tabulated to identify passing and failing of various tests for each of the candidate bit sequences. In this instance, S2 and S4 are rejected for having positive scores for Test(2) and Test(4) respectively. The bit sequence S3 is shown to have the lowest score in Test(1), Test(3), and Test(4) and may be selected as the best bit sequence, Sb.

TABLE 3

| Candidate | Test (1) | Test (2) | Test (3) | Test (4) |
|---|---|---|---|---|
| S1 | Score(1, | Score(1, 2) < 0 | Score(1, 3) < 0 | Score(1, 4) < 0 |
| | 1) < 0 | | | |
| S2 | Score(2, | Score(2, 2) > 0 | Score(2, 3) < 0 | Score(2, 4) < 0 |
| | 1) < 0 | | | |
| S3 | Score(3, | Score(3, 2) < 0 | Score(3, 3) < 0 | Score(3, 4) < 0 |
| | 1) < 0 | | | |
| S4 | Score(4, | Score(4, 2) < 0 | Score(4, 3) < 0 | Score(4, 4) > 0 |
| | 1) < 0 | | | |
| S5 | Score(5, | Score(5, 2) < 0 | Score(5, 3) < 0 | Score(5, 4) < 0 |
| | 1) < 0 | | | |
| Minimum | S3 | S5 | S3 | S3 |
| score | | | | |
| sequence | | | | |

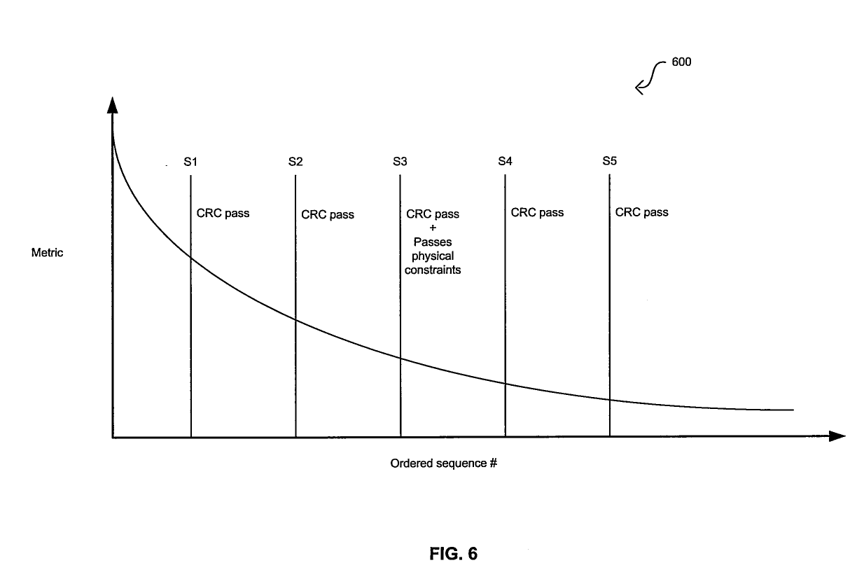

FIG. 6 is a graph illustrating exemplary set of sequences that meets CRC and audio physical constraints, in accordance with an embodiment of the invention. Referring to FIG. 6, there is shown the result of the redundancy algorithm. For example, the search process for T hypothesis as shown in FIGS. 5A-5C may result in the set of bit sequences {S1, S2, S3, S4, and S5} associated with the decoding of a received audio frame or bit sequence comprising audio content. These bit sequences may be selected based on their metric values and passing the CRC verification. The set of bit sequences may also be required to pass physical constraint tests associated with the encoded audio content as described herein. In this instance, the bit sequence S3 has been shown to meet the CRC verification and the physical constraint test and may be selected as the best bit sequence, Sb.

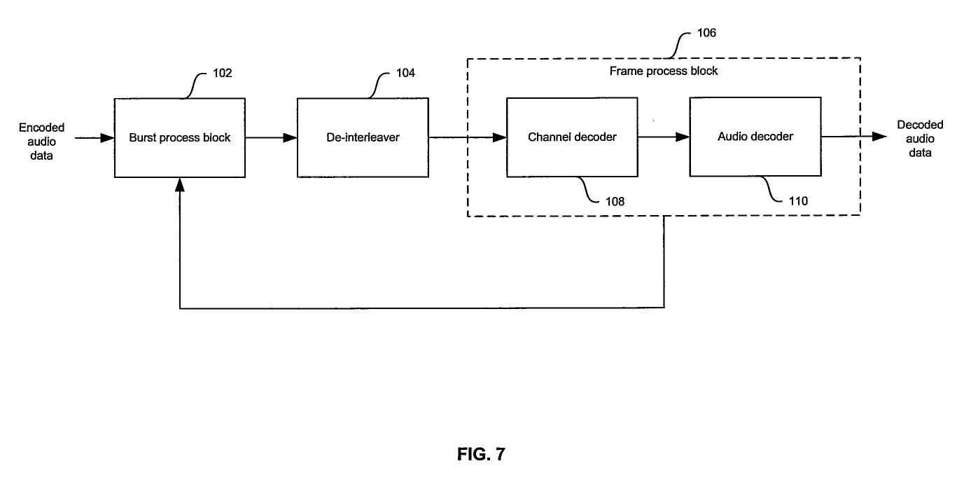

FIG. 7 is a block diagram illustrating an iterative multilayer approach for improving audio content decoding when burst processing is utilized, in accordance with an embodiment of the invention. Referring to FIG. 7, there is shown the receiver 100 in FIG. 1 with a feedback signal from the frame process portion of the multilayer decoding approach to the burst process portion of the multilayer decoding approach. The frame process may comprise the use of redundancy verification of the results generated by the Viterbi algorithm and the use of physical constraints to reduce decoding errors in decoded audio content that may result from utilizing the standard Viterbi algorithm. The burst process may utilize information decoded in the frame process block 106 as an input to improve the channel estimation and channel equalization operations in the burst process block 102.

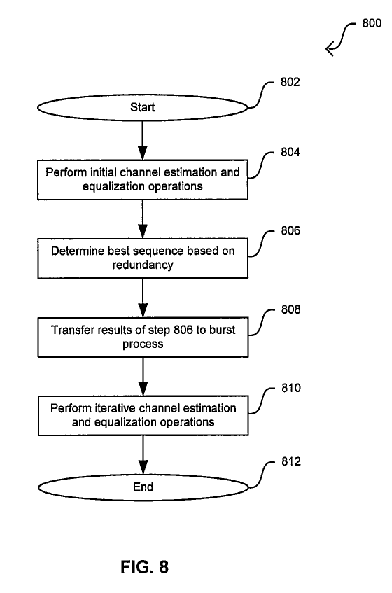

FIG. 8 is a flow diagram illustrating exemplary steps in the iterative multilayer approach for improving audio content decoding, in accordance with an embodiment of the invention. Referring to FIG. 8, after start step 802, in step 804, an initial or first iteration of a channel estimation operation and of an equalization operation may be performed on received audio signals during a burst process portion of the multilayer decoding approach. The first iteration of the channel estimation operation and the first iteration of the equalization operation may be performed by, for example, the burst process block 102 in FIG. 7. In step 806, decoding of a received audio frame may be performed during the frame processing portion of the multilayer decoding approach. The frame processing may be performed by, for example, the frame process block 106 in FIG. 7. The frame processing may be based on results from the burst processing in step 804. In step 808, at least a portion of the results generated in step 806 by the frame process portion of the multilayer decoding approach may be transferred from, for example, the frame process block 106 to the burst process block 102 via a feedback signal. In step 810, the burst processing may perform a second iteration of the channel estimation operation and/or a second iteration of the equalization operation based on the decoded results provided from the frame process portion of the multilayer decoding approach. After step 810, the operation may proceed to end step 812. The improved results of the burst process may be further interleaved and subsequently processed by the frame process. The frame process may utilize a standard frame process or determine the best sequence that may be utilized based on, for example, redundancy in the audio content.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for signal processing, the method comprising:
generating a corresponding redundancy verification parameter for a decoded bit sequence that comprises audio content;
verifying said decoded bit sequence based on said corresponding redundancy verification parameter; and
if said decoded bit sequence fails said verification, subsequently decoding said bit sequence previously decoded by imposing at least one physical constraint resulting from encoding of said audio content.

2. The method according to claim 1, wherein said decoded bit sequence is a decoded audio frame.

3. The method according to claim 2, wherein said redundancy verification parameter for said decoded audio frame is one of the following: a cyclic redundancy check (CRC) value and a length of frame value.

4. The method according to claim 2, wherein said decoded audio frame comprises a portion that corresponds to a CRC value.

5. The method according to claim 2, wherein said decoded audio frame comprises a header portion.

6. The method according to claim 4, wherein said header portion comprises at least one portion for determining a length of frame value.

7. The method according to claim 6, wherein said at least one portion corresponds to at least one of the following: a length of frame value, a bitrate value, a sampling rate frequency value, and a frame padding value.

8. A machine-readable storage having stored thereon, a computer program having at least one code section for signal processing, the at least one code section being executable by a machine for causing the machine to perform steps comprising:
generating a corresponding redundancy verification parameter for a decoded bit sequence that comprises audio content;
verifying said decoded bit sequence based on said corresponding redundancy verification parameter; and
if said decoded bit sequence fails said verification, subsequently decoding said bit sequence previously decoded by imposing at least one physical constraint resulting from encoding of said audio content.

9. The machine-readable storage according to claim 8, wherein said decoded bit sequence is a decoded audio frame.

10. The machine-readable storage according to claim 9, wherein said redundancy verification parameter for said decoded audio frame is one of the following: a cyclic redundancy check (CRC) value and a length of frame value.

11. The machine-readable storage according to claim 9, wherein said decoded audio frame comprises a portion that corresponds to a CRC value.

12. The machine-readable storage according to claim 9, wherein said decoded audio frame comprises a header portion.

13. The machine-readable storage according to claim 12, wherein said header portion comprises at least one portion for determining a length of frame value.

14. The machine-readable storage according to claim 13, wherein said at least one portion corresponds to at least one of the following: a length of frame value, a bitrate value, a sampling rate frequency value, and a frame padding value.

15. A system for signal processing, the system comprising:
at least one processor that enables generating a corresponding redundancy verification parameter for a decoded bit sequence that comprises audio content;
said at least one processor enables verifying said decoded bit sequence based on said corresponding redundancy verification parameter; and
if said decoded bit sequence fails said verification, said at least one processor enables subsequently decoding said bit sequence previously decoded by imposing at least one physical constraint resulting from encoding of said audio content.

16. The system according to claim 15, wherein said decoded bit sequence is a decoded audio frame.

17. The system according to claim 16, wherein said redundancy verification parameter for said decoded audio frame is one of the following: a cyclic redundancy check (CRC) value and a length of frame value.

18. The system according to claim 16, wherein said decoded audio frame comprises a portion that corresponds to a CRC value.

19. The system according to claim 16, wherein said decoded audio frame comprises a header portion.

20. The system according to claim 19, wherein said header portion comprises at least one portion for determining a length of frame value.

21. The system according to claim 20, wherein said at least one portion corresponds to at least one of the following: a length of frame value, a bitrate value, a sampling rate frequency value, and a frame padding value.
